(19) United States
(12) Patent Application Publication
(10) Pub. No.: US 2006/0158357 A1
(43) Pub. Date: Jul. 20, 2006

(54) Text compression method for multi-level display

(75) Inventor: J. William Whikehart, Novi, MI (US)

Correspondence Address: VISTEON, C/O BRINKS HOFER GILSON & LIONE, PO BOX 10395, CHICAGO, IL, 60610, US

(73) Assignee: Visteon Global Technologies, Inc.

(21) Appl. No.: 11/039,289

(22) Filed: Jan. 19, 2005

(51) Int. Cl. H03M 7/00

(52) U.S. Cl. 341/90; 382/232; 382/245; 382/246

(57) ABSTRACT

A text compression and multi-level display system, including a receiver, a processor, and a display device, is provided. The receiver is adapted to receive a digital audio transmission and generate a digital signal including a text and a text display level corresponding to the text. The processor is in communication with the receiver to receive the digital signal. The processor compares a stored display level with the text display level of the digital signal to generate a display decision. The processor communicates the text to the display device based on the display decision. As such, the text will be displayed based on the stored display level and the text display level.

### BACKGROUND

1. Field of the Invention

The present invention generally relates to a system for text compression.

2. Description of Related Art

Systems such as digital audio broadcast receivers may receive data content in addition to the data used for the digital audio signal itself. The additional data may be program-associated data, such as a song title and artist for the song being received via the digital audio transmission. At least some, if not most, of the program-associated data content will be in text form.

Each type of receiver may have different information display capabilities. For example, a lower-end receiver may have a single-line, 12-character alphanumeric display. In this system, it would be impossible to display all of the program-associated data simultaneously. However, in high-end systems the display device may have a multi-line display and all the program-associated information could be displayed at the same time.

For systems with a small display, one solution is to scroll the data across the display. This approach may be undesirable because not all information is seen at the same time.

Another approach is to send multiple versions of the data to accommodate different display capabilities in different receivers. The disadvantage of sending different versions of the data is that certain parts of the data may be sent more than once, thus requiring additional bandwidth in the transmitted signal.

Yet another solution is to use a text compression algorithm in the receiver, to shorten text content to fit smaller displays. A text compression algorithm in the receiver has two disadvantages. The first disadvantage is that the algorithms generally do not account for the context of the message and, therefore, may result in mangled, unrecognizable abbreviated text. The second disadvantage is that a complicated compression algorithm would require significant processing resources adding cost and complexity to the receiver.

In view of the above, it is apparent that there exists a need for an improved system and method for text compression.

### SUMMARY

In satisfying the above need, as well as overcoming the enumerated drawbacks and other limitations of the related art, the present invention provides a system and method for multiple level text compression.

The system includes a receiver, a processor, and a display device. The receiver is adapted to receive a digital audio transmission and generate a digital signal including a text component and a text display level corresponding to the text component. The processor is in communication with the receiver to receive the digital signal. The processor compares a stored display level with the text display level of the digital signal to generate a display decision. The processor communicates the text to the display device based on the display decision. As such, the text will be displayed based on the stored display level and the text display level.

Generally, the text is a single character and the text display level corresponds to a display level for the character. As such, a string of characters may be used to form a message. Further, each character may be displayed or omitted by a receiver based on that character's corresponding text display level. The bits defining the character and the bits defining the text display level are integrated into a single packet within the digital signal. Packets are groupings of bits that may be defined by time, organization, or otherwise delimited. Typically, each packet is one byte with certain bits allocated to the text display level and the remaining bits allocated to identify the character. If the processor determines the characters are to be communicated to the display device, the characters are mapped to a standard character set, such as, an ASCII character set. In addition, the processor is configured to identify a predetermined character code in the text and communicate a subsequent packet or byte to the display device when the predetermined character code is identified. As such, the reduced bit range used for character identification may be used to send any character contained in a full eight (8) bit standard character set.

Further objects, features and advantages of this invention will become readily apparent to persons skilled in the art after a review of the following description, with reference to the drawings and claims that are appended to and form a part of this specification.

### BRIEF DESCRIPTION OF THE DRAWINGS

FIG. 1 is a schematic view of a digital audio system including text compression logic in accordance with present invention.

### DETAILED DESCRIPTION

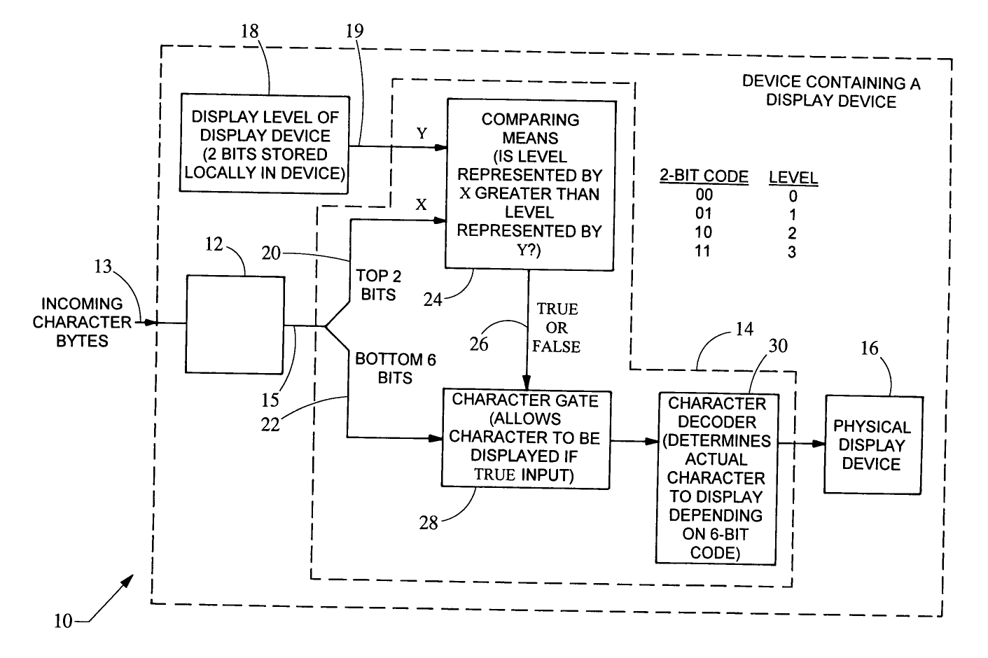

Referring now to FIG. 1, a system embodying the principles of the present invention is illustrated therein and designated at 10. As its primary components, the system 10 includes a receiver 12, a processor 14, and a display device 16.

The receiver 12 receives a digital audio transmission 13, such as a satellite radio transmission. The digital audio transmission includes encoded text and text display information embedded therein. The receiver 12 transforms the digital audio transmission 13 into a digital signal 15 that is provided to the processor 14. The digital signal 15 includes a series of 8-bit packets of text information. Each 8-bit packet corresponds to a single character where the top two (2) bits are a text display level 20 and the bottom six (6) bits designate the text 22 to be displayed.

The processor 14 retrieves a stored display level 19 from a memory device 18. In block 24, the stored display level 19 is compared to the text display level 20 to generate a display decision 26 indicating if the text 22 is to be physically displayed. If the display decision 26 indicates the text 22 is to be displayed, the text 22 is provided from block 28 to block 30. Otherwise, the text 22 is omitted and not provided for further display. In block 30, the text 22 may be mapped to a standard character set. As such, the bottom six (6) bits of the digital signal 15 may be mapped to a 128-bit ASCII character set to be provided to the display device 16.

A character coding method is used to indicate which characters are to be displayed based on the corresponding text display level 20. In one method, the characters associated with the highest text display level will always be displayed, and characters that do not need to be displayed will systematically be omitted to form abbreviated messages to fit smaller displays. For example, if it is assumed that characters are stored as one character/byte packets, then six (6) bits of the byte can be used for the actual character code or text 22, and two (2) bits can be used to indicate the text display level 20 of the character. Therefore, four (4) possible display levels exist, 0-3. If the text display level 20 is a binary 00, indicating level 0, the associated character is displayed in all receivers. If the text display level 20 is a binary 11, indicating level 3, the character is displayed in only the highest-level receivers, capable of supporting many characters simultaneously. If the text display level 20 is 10 or 01, the character is displayed or omitted based on context of the message for each level of receiver display. Other packet sizes and display level to character identification ratios are also contemplated, such as the text display level 20 might only use 1 bit indicating low or high and 7 bits may be used for the actual character identification.

The character coding described above is performed at the signal transmission end. The system only has to decode the text display level 20 as each packet is received, and compare the text display level 20 to the stored display level 19 of the system. The stored display level 19 may be determined at the time of receiver design or manufacture. The coding of the transmission is performed either by a human operator or an algorithm running on a machine. If a human operator performs the coding, the operator can use human judgment to determine the best coding using various guides, such as common sense, cultural guides, or alternative forms of words that are well known by the public. For example, if a song title to be transmitted is “PLEASE PLEASE ME”, which has 16 characters, it might be coded such that in low-level receivers an abbreviated message, such as, “PLS PLS ME” is displayed.

A more detailed example is provided in Table 1. The transmission includes the message, “The accident is at the intersection of Highway I-94 and Southfield Road”.

TABLE 1

| | | | Next byte | | | | |
|---|---|---|---|---|---|---|---|
| | | | of bottom | Desired | Desired | Desired | Desired |
| | | Bottom 6 | 6 bits is | text to be | text to be | text to be | text to be |
| | Top 2 bits | bits in | Special | displayed | displayed | displayed | displayed |
| | in Integer | integer | Character | on Level | on Level | on Level | on Level |
| Character | Form | form | Code | 3 receiver | 2 receiver | 1 receiver | 0 receiver |
| T | 1 | 20 | | T | T | | |
| h | 1 | 34 | | h | h | | |
| e | 1 | 31 | | e | e | | |
| | 3 | 0 | | | | | |
| a | 3 | 27 | | a | a | a | A |
| c | 3 | 29 | | c | c | c | C |
| c | 0 | 29 | | c | | | |
| i | 0 | 35 | | i | | | |
| d | 3 | 30 | | d | d | d | D |
| e | 0 | 31 | | e | | | |
| n | 3 | 40 | | n | n | n | N |
| t | 3 | 46 | | t | t | t | T |
| | 3 | 0 | | | | | |
| i | 1 | 35 | | i | i | | |
| s | 1 | 45 | | s | s | | |
| | 3 | 0 | | | | | |
| a | 2 | 27 | | a | a | a | |
| t | 2 | 46 | | t | t | t | |
| | 3 | 0 | | | | | |
| t | 1 | 46 | | t | t | | |
| h | 1 | 34 | | h | h | | |
| e | 1 | 31 | | e | e | | |
| | 3 | 0 | | | | | |
| i | 2 | 35 | | i | i | i | |
| n | 2 | 40 | | n | n | n | |
| t | 2 | 46 | | t | t | t | |
| e | 0 | 31 | | e | | | |
| r | 2 | 44 | | r | r | r | |
| s | 2 | 45 | | s | s | s | |
| e | 0 | 31 | | e | | | |
| c | 2 | 29 | | c | c | c | |
| t | 2 | 46 | | t | t | t | |
| i | 0 | 35 | | i | | | |
| o | 0 | 41 | | o | | | |
| n | 2 | 40 | | n | n | n | |
| | 3 | 0 | | | | | |
| o | 1 | 41 | | o | o | | |
| f | 1 | 32 | | f | f | | |
| | 3 | 0 | | | | | |
| H | 3 | 8 | | H | H | H | H |
| i | 0 | 35 | | i | | | |
| g | 0 | 33 | | g | | | |
| h | 0 | 34 | | h | | | |
| w | 3 | 49 | | w | w | w | W |
| a | 0 | 27 | | a | | | |
| y | 3 | 51 | | y | y | y | Y |
| | 3 | −38 | | | | | |
| I | 3 | 9 | | I | I | I | I |
| - | NA | 63 | 45 | - | - | | |
| 9 | 3 | 62 | | 9 | 9 | 9 | 9 |
| 4 | 3 | 57 | | 4 | 4 | 4 | 4 |
| | 3 | 0 | | | | | |
| a | 2 | 27 | | a | a | a | |
| n | 2 | 40 | | n | n | n | |
| d | 2 | 30 | | d | d | d | |
| | 3 | 0 | | | | | |
| S | 3 | 19 | | S | S | S | S |
| o | 2 | 41 | | o | o | o | |
| u | 2 | 47 | | u | u | u | |
| t | 3 | 46 | | t | t | t | T |
| h | 3 | 34 | | h | h | h | H |
| f | 3 | 32 | | f | f | f | F |
| i | 2 | 35 | | i | i | i | |
| e | 2 | 31 | | e | e | e | |
| L | 3 | 38 | | l | l | l | L |
| d | 3 | 30 | | d | d | d | D |
| | 3 | 0 | | | | | |
| R | 3 | 18 | | R | R | R | R |
| o | 1 | 41 | | o | | | |
| a | 1 | 27 | | a | | | |
| d | 3 | 30 | | d | d | d | D |
| | NA | 63 | 46 | | | | |
| EXT | 3 | 63 | 3 | EXT | EXT | EXT | EXT |

The full message is 72 characters in length, and if the stored display level is level 3, the entire 72 character message is displayed. If the stored display level is level 2, characters with an associated text display level greater than 0 are displayed and the message is abbreviated to “The acdnt is at the intrsctn of Hwy I-94 and Southfield Rd.” A stored display level of level 2 results in a displayed message of 59 characters, corresponding to an 18% compression. If the stored display level is level 1, characters with an associated text display level greater than 1 are displayed. Accordingly, the abbreviated message “acdnt at intrsctn Hwy I94 and Southfield Rd.” is displayed. A stored display level of level 1 results in a displayed message of 43 characters, corresponding to a 40% compression. On level 0, only characters with an associated text display level of 3 are displayed, therefore, the resulting message is “acdnt intrsctn Hwy I94 Sthfid Rd.” On level 0, the displayed message length is 32 characters, resulting in a 66% compression or reduction in length.

It should be noted that code 63 is used in conjunction with a second packet or byte to indicate the “-” character. Code 63 is used to indicate that the actual character is contained in the following byte, using a full 8-bit coding. In this instance, the second byte is 45 or the ASCII code for “-”. As shown in Table 2, the following condensed coding structure is used.

TABLE 2
CODING FOR BOTTOM 6 BITS

| CHARACTER | CODE |
|---|---|
| Space | 0 |
| a | 1 |
| b | 2 |
| c | 3 |
| d | 4 |
| e | 5 |
| f | 6 |
| g | 7 |
| h | 8 |
| i | 9 |
| j | 10 |
| k | 11 |
| l | 12 |
| m | 13 |
| n | 14 |
| o | 15 |
| p | 16 |
| q | 17 |
| r | 18 |
| s | 19 |
| t | 20 |
| u | 21 |
| v | 22 |
| w | 23 |
| x | 24 |
| y | 25 |
| z | 26 |
| A | 27 |
| B | 28 |
| C | 29 |
| D | 30 |
| E | 31 |
| F | 32 |
| G | 33 |
| H | 34 |
| I | 35 |
| J | 36 |
| K | 37 |
| L | 38 |
| M | 39 |
| N | 40 |
| O | 41 |
| P | 42 |
| Q | 43 |
| R | 44 |
| S | 45 |
| T | 46 |
| U | 47 |
| V | 48 |
| W | 49 |
| X | 50 |
| Y | 51 |
| Z | 52 |
| 0 | 53 |
| 1 | 54 |
| 2 | 55 |
| 3 | 56 |
| 4 | 57 |
| 5 | 58 |
| 6 | 59 |
| 7 | 60 |
| 8 | 61 |
| 9 | 62 |
| Special | 63 |
| Character | |

Codes 1-26 are used for lower-case letters, while codes 27-52 are used for upper-case letters, and codes 53-62 are used for the numerals 0 to 9. In addition, code 0 is used to indicate a space character.

As a person skilled in the art will readily appreciate, the above description is meant as an illustration of implementation of the principles this invention. This description is not intended to limit the scope or application of this invention in that the invention is susceptible to modification, variation and change, without departing from spirit of this invention, as defined in the following claims.

I/We claim:

1. A system for multiple level text compression, the system comprising:
a receiver adapted to receive the digital audio transmission and generate a digital signal including text and a text display level corresponding to the text;
a processor in communication with the receiver to receive the digital signal and compare a stored display level with the text display level to generate a display decision; and
a display device in communication with the receiver, wherein the processor is configured to communicate the text to the display device based on the display decision.

2. The system according to claim 1, wherein the text is a single character and the text display level corresponds to the character.

3. The system according to claim 2, wherein the single character and text display level are included in a single packet of the digital signal.

4. The system according to claim 3, wherein the single packet is one byte.

5. The system according to claim 4, wherein processor is configured to map the text to standard character set.

6. The system according to claim 5, wherein the standard character set is an ASCII character set.

7. The system according to claim 3, wherein the processor is configured to identify a predetermined character code in the text and communicate a subsequent bit packet to the display device.

8. The system according to claim 7, wherein the subsequent bit packet is communicated to the display device based on the text display level.

9. The system according to claim 8, wherein the subsequent bit packet corresponds to a standard character set.

10. The system according to claim 9, wherein the standard character set is an ASCII character set.

11. A method for multiple level text compression, the method comprising:
receiving a digital audio transmission;
generating a digital signal including text and a text display level;
comparing the text display level to a stored display level to generate a display decision; and
displaying the text on a display device based on the display decision.

12. The method according to claim 11, wherein the text is a single character and the text display level corresponds to the character.

13. The method according to claim 12, wherein the single character and text display level are included in a single packet of the digital signal.

14. The method according to claim 13, wherein the single packet is one byte.

15. The method according to claim 14, wherein processor is configured to map the text to standard character set.

16. The method according to claim 15, wherein the standard character set is an ASCII character set.

17. The method according to claim 13, wherein the processor is configured to identify a predetermined character code in the text and communicate a subsequent bit packet to the display device.

18. The method according to claim 17, wherein the subsequent bit packet is communicated to the display device based on the text display level.

19. The method according to claim 18, wherein the subsequent bit packet corresponds to a standard character set.

20. The method according to claim 19, wherein the standard character set is an ASCII character set.
